(19) United States
(12) Patent Application Publication
(10) Pub. No.: US 2026/0082946 A1
(43) Pub. Date: Mar. 19, 2026

(54) SEMICONDUCTOR DEVICE AND METHOD FOR MANUFACTURING THE SAME

(71) Applicant: FUJI ELECTRIC CO., LTD., Kawasaki-shi (JP)

(72) Inventor: Hayato NAKANO, Kofu-city (JP)

(73) Assignee: FUJI ELECTRIC CO., LTD., Kawasaki-shi (JP)

(21) Appl. No.: 19/307,865

(22) Filed: Aug. 22, 2025

(30) Foreign Application Priority Data
Sep. 17, 2024 (JP) 2024-160059

(51) Int. Cl. H01L 23/538; H01L 23/00; H01L 25/07; H05K 1/02; H05K 3/34

(52) U.S. Cl. CPC H10W 70/60; H05K 1/0298; H05K 3/3447; H10W 70/611; H10W 90/00; H05K 2201/10166; H05K 2201/10318; H05K 2201/10939; H05K 2203/107; H10W 72/07236; H10W 72/877; H10W 90/724; H10W 90/734

(57) ABSTRACT

A semiconductor device, including: a semiconductor chip having a plurality of main electrodes and a gate electrode; a first substrate on which the semiconductor chip is mounted; a second substrate located above the first substrate, the second substrate having a conductive plate on a front surface thereof, the conductive plate being electrically connected to the semiconductor chip; and a case having an opening in an upper surface thereof, at least a part of the conductive plate being exposed through the opening, the case incorporating the semiconductor chip, the first substrate, and the second substrate.

### CROSS-REFERENCE TO RELATED APPLICATION

This application is based upon and claims the benefit of priority of the prior Japanese Patent Application No. 2024-160059, filed on Sep. 17, 2024, the entire contents of which are incorporated herein by reference.

### BACKGROUND OF THE INVENTION

### 1. Field of the Invention

The embodiments discussed herein relate to a semiconductor device and a method for manufacturing the same.

### 2. Background of the Related Art

There has been proposed a semiconductor device in which an opening is formed in a sealing resin of the semiconductor device to expose a conductor portion formed on a substrate on which a semiconductor chip is mounted, and in which a terminal and an electronic component are connected to the exposed conductor portion (see, for example, the following Patent Literatures (1) to (8)).
(1) Japanese Laid-open Patent Publication No. 2002-289316
(2) Japanese Laid-open Patent Publication No. 2004-228595
(3) Japanese Laid-open Patent Publication No. 2002-289761
(4) Japanese Laid-open Patent Publication No. 2024-000071
(5) Japanese Laid-open Patent Publication No. 2014-082101
(6) Japanese Laid-open Patent Publication No. 2013-135161
(7) International Publication Pamphlet No. WO 2009/081723
(8) International Publication Pamphlet No. WO 2021/059947

### SUMMARY OF THE INVENTION

According to an aspect of the present disclosure, there is provided a semiconductor device including: a semiconductor chip having a plurality of main electrodes and a gate electrode; a first substrate on which the semiconductor chip is mounted; a second substrate located above the first substrate, the second substrate having a conductive plate on a front surface thereof, the conductive plate being electrically connected to the semiconductor chip; and a case having an opening in an upper surface thereof, at least a part of the conductive plate being exposed through the opening, the case incorporating the semiconductor chip, the first substrate, and the second substrate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a top view of an example of a semiconductor device according to a first embodiment;

FIG. 2 illustrates a part of a side surface viewed from the +X direction of FIG. 1 (excluding a sealing resin);

FIG. 3 is a sectional view illustrative of a part of a section taken along the line III-III in FIG. 1;

FIG. 4 is a top view of an example of a first substrate on which a semiconductor chip is mounted;

FIG. 5 is a top view of an example of a second substrate;

FIG. 6 illustrates an example of the circuit structure of the semiconductor device;

FIG. 7 is a sectional view illustrative of an example of terminal connection;

FIG. 8 illustrates the relationship between the area of an exposed portion of a conductive plate and the area of a connection portion of a terminal;

FIG. 9 illustrates an example of a method for manufacturing the semiconductor device according to the first embodiment;

FIG. 10 is a top view of an example of a semiconductor device according to a second embodiment;

FIG. 11 is a sectional view illustrative of a part of a section taken along the line XI-XI in FIG. 10; and

FIG. 12 is a top view of an example of a second substrate in the semiconductor device according to the second embodiment.

### DETAILED DESCRIPTION OF THE INVENTION

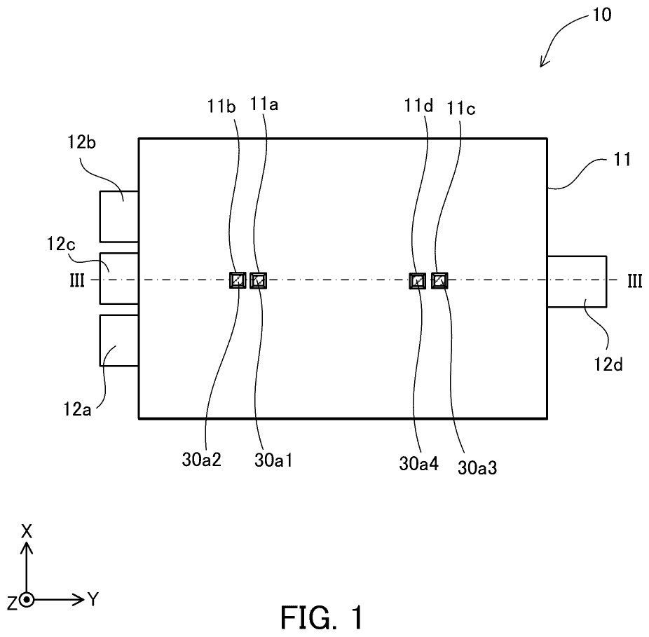

Embodiments will now be described with reference to the drawings. In the following description, a “front surface” or an “upper surface” indicates an X-Y plane which faces the upper side (+Z direction) in, for example, a semiconductor device 10 of FIG. 1. Similarly, an “upside” indicates the upward direction (+Z direction) in the semiconductor device 10 of FIG. 1. A “back surface” or a “lower surface” indicates the X-Y plane which faces the lower side (−Z direction) in the semiconductor device 10 of FIG. 1. Similarly, a “downside” indicates the downward direction (−Z direction) in the semiconductor device 10 of FIG. 1. These terms mean the same directions at need in the other drawings. The “front surface,” the “upper surface,” the “upside,” the “back surface,” the “lower surface,” the “downside,” and a “side surface” are simply used as expedient representation for specifying relative positional relationships and do not limit the technical idea of the present disclosure. For example, the “upside” or the “downside” does not always mean the vertical direction relative to the ground. That is to say, a direction indicated by the “upside” or the “downside” is not limited to the gravity direction.

### First Embodiment

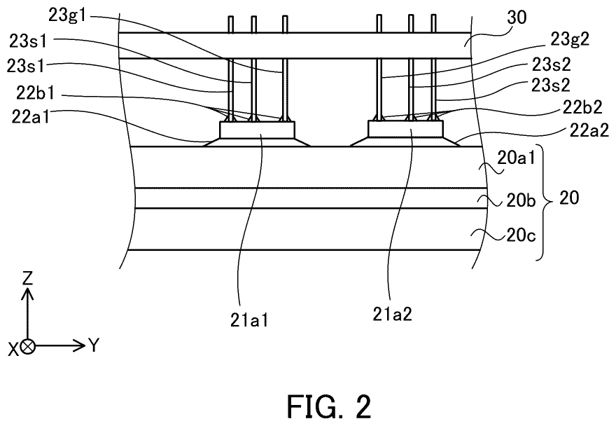

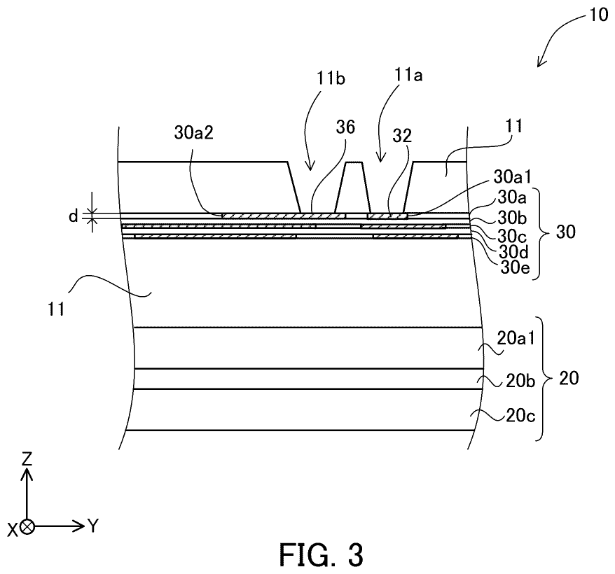

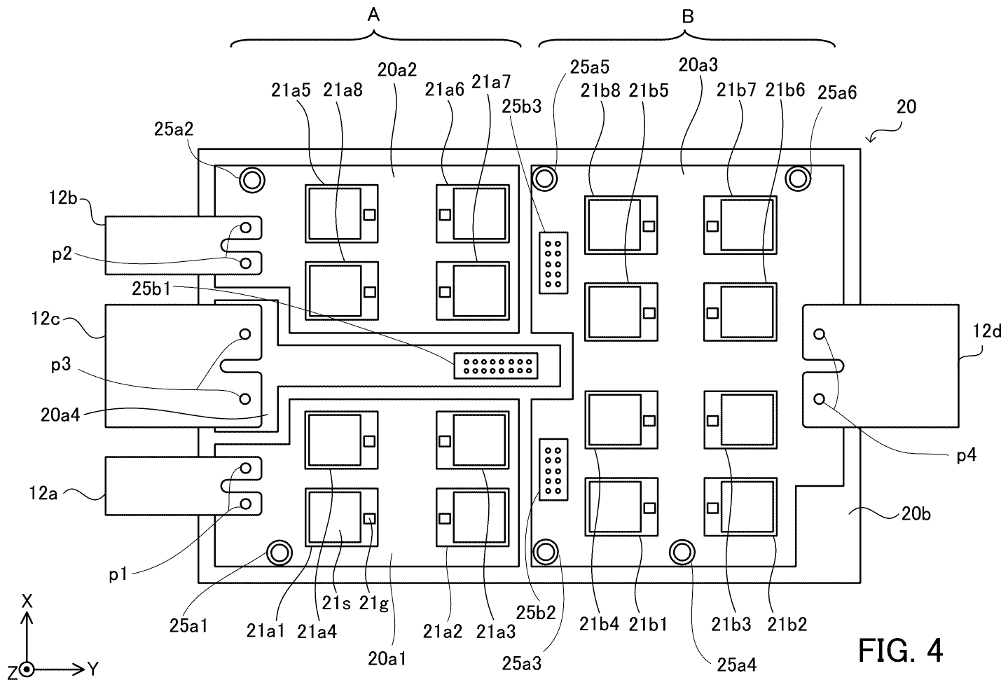

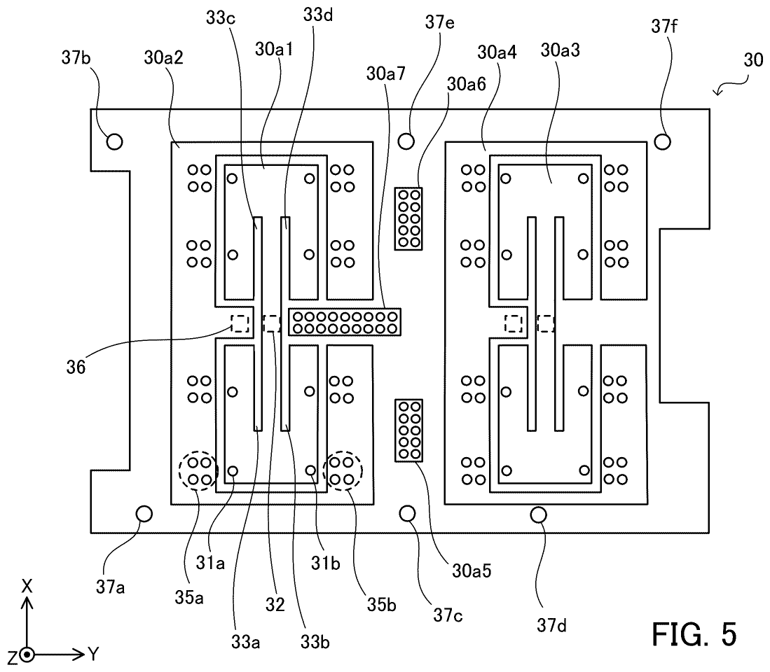

FIG. 1 is a top view of an example of a semiconductor device according to a first embodiment. FIG. 2 illustrates a part of a side surface viewed from the +X direction of FIG. 1 (excluding a sealing resin). FIG. 3 is a sectional view illustrative of a part of a section taken along the line III-III in FIG. 1. FIG. 4 is a top view of an example of a first substrate on which a semiconductor chip is mounted. FIG. 5 is a top view of an example of a second substrate.

As illustrated in FIG. 4, a semiconductor device 10 includes semiconductor chips 21a1 to 21a8 and 21b1 to 21b8. The semiconductor chips 21a1 to 21a8 and 21b1 to 21b8 are mounted on a first substrate 20.

In the present embodiment, the semiconductor device 10 has a module structure of a half-bridge circuit including an upper arm portion A and a lower arm portion B. The upper arm portion A includes the semiconductor chips 21a1 to 21a8. The lower arm portion B of the semiconductor device 10 includes the semiconductor chips 21b1 to 21b8.

Each of the semiconductor chips 21a1 to 21a8 and 21b1 to 21b8 has a plurality of main electrodes (also referred to as an input electrode and an output electrode) and a gate electrode (also referred to as a control electrode). For example, as illustrated in FIG. 4, the semiconductor chip 21a1 includes a main electrode 21s and a gate electrode 21g on the upper surface. The semiconductor chip 21a1 includes another main electrode (not illustrated) on the back surface. The other semiconductor chips 21a2 to 21a8 and 21b1 to 21b8 also have the same electrode structure as that of the semiconductor chip 21a1.

The semiconductor chips 21a1 to 21a8 and 21b1 to 21b8 may contain silicon carbide as a main component. Such a semiconductor chip is, for example, a power metal-oxide-semiconductor field-effect transistor (MOSFET). In this case each semiconductor chip includes a drain electrode, which is one of the main electrodes, on the lower surface, and includes a gate electrode and a source electrode, which is one of the main electrodes, on the upper surface.

Furthermore, the semiconductor chips 21a1 to 21a8 and 21b1 to 21b8 may contain silicon as a main component. Such a semiconductor chip may include a reverse-conducting insulated gate bipolar transistor (RC-IGBT) having both of the function of an IGBT and the function of a free wheeling diode (FWD). In this case, each semiconductor chip includes a collector electrode, which is one of main electrodes, on the lower surface, and includes a gate electrode and an emitter electrode, which is one of the main electrodes, on the upper surface. In the present embodiment, a case where the semiconductor chips 21a1 to 21a8 and 21b1 to 21b8 are power MOSFETs will be described as an example, but the present disclosure is not limited to this embodiment.

As illustrated in FIGS. 2 to 4, the first substrate 20 on which the semiconductor chips 21a1 to 21a8 and 21b1 to 21b8 are mounted includes conductive plates 20a1 to 20a4, a resin layer 20b, and a metal plate 20c. The conductive plates 20a1 to 20a4 are formed on the front surface of the resin layer 20b and the metal plate 20c is formed on the back surface of the resin layer 20b.

The conductive plates 20a1 and 20a2 are formed in the upper arm portion A and the conductive plate 20a3 is formed in the lower arm portion B. The conductive plate 20a4 extends from the center to the outer edge of the first substrate 20 and is formed in the central portion of the region of the upper arm portion A on the resin layer 20b.

The conductive plates 20a1 to 20a4 are made of metal having good electrical conductivity. Such metal is, for example, copper, aluminum, or an alloy containing at least one of them. In order to improve the corrosion resistance of the conductive plates 20a1 to 20a4, plating treatment may be performed. A plating material used in this case is, for example, nickel, a nickel-phosphorus alloy, or a nickel-boron alloy.

The resin layer 20b is rectangular in plan view. Corner portions of the resin layer 20b may be R-chamfered or C-chamfered. The resin layer 20b is made of a resin material. Epoxy resin to which a filler having an insulating property and higher thermal conductivity than the resin material is added may be used as the resin material.

The metal plate 20c contains, as a main component, metal having excellent thermal conductivity. Such metal is, for example, copper, aluminum, or an alloy containing at least one of them. In order to improve the corrosion resistance of the metal plate 20c, plating treatment may be performed. A plating material used in this case is, for example, nickel, a nickel-phosphorus alloy, or a nickel-boron alloy.

In the example of FIG. 4, the semiconductor chips 21a1 to 21a4 and an external terminal 12a are mounted on the conductive plate 20a1 and the semiconductor chips 21a5 to 21a8 and an external terminal 12b are mounted on the conductive plate 20a2. Furthermore, the semiconductor chips 21b1 to 21b8 and an external terminal 12d are mounted on the conductive plate 20a3. An external terminal 12c is mounted on the conductive plate 20a4.

As illustrated in FIG. 2, the semiconductor chips 21a1 and 21a2 are electrically connected to the conductive plate 20a1 by bonding materials 22a1 and 22a2, respectively. One ends of a plurality of post electrodes (also referred to as wiring pins or the like) 23s1 and 23s2 are connected to the source electrodes of the semiconductor chips 21a1 and 21a2 by bonding materials 22b1 and 22b2, respectively. Furthermore, the other ends of the post electrodes 23s1 and 23s2 are connected to a second substrate 30. Moreover, one ends of post electrodes 23g1 and 23g2 are connected to the gate electrodes of the semiconductor chips 21a1 and 21a2 by bonding materials 22b1 and 22b2, respectively. In addition, the other ends of the post electrodes 23s1, 23s2, 23g1, and 23g2 are connected to the second substrate 30. Although not illustrated, the other semiconductor chips 21a3 to 21a8 and 21b1 to 21b8 are connected to one of the conductive plates 20a1 to 20a3 and are connected to the second substrate 30, in the same way.

Furthermore, although not illustrated in FIG. 2, the external terminal 12a is connected to the conductive plate 20a1 by a bonding material and the external terminal 12b is connected to the conductive plate 20a2 by a bonding material. In addition, the external terminal 12c is connected to the conductive plate 20a4 by a bonding material and the external terminal 12d is connected to the conductive plate 20a3 by a bonding material. The external terminals 12a to 12d may be connected to the respective conductive plates of the first substrate 20 by laser welding or ultrasonic welding.

The external terminals 12a and 12b are P terminals which function as terminals on the positive electrode side in the half-bridge circuit, and the external terminal 12c is an N terminal which functions as a terminal on the negative electrode side in the half-bridge circuit. Furthermore, the external terminal 12d is an output terminal of the half-bridge circuit. As illustrated in FIG. 4, bosses p1, p2, p3, and p4 protruding toward the first substrate 20 are formed at portions of the external terminals 12a to 12d with which the bonding materials are in contact. The bosses p1, p2, p3, and p4 may be formed by press working when the external terminals 12a to 12d are formed. The thickness of the bonding materials is ensured by the height of the bosses.

For example, solder is used as the above bonding materials (for example, as the bonding materials 22a1, 22a2, 22b1, 22b2, and the like). Lead-free solder is used as the solder. The lead-free solder contains as a main component, for example, at least one of a tin-silver-copper alloy, a tin-zinc-bismuth alloy, a tin-copper alloy, and a tin-silver-indium-bismuth alloy. Instead of the solder, a sintered metal body may be used. A material for the sintered metal body is silver, gold, nickel, copper, or an alloy containing at least one of them.

Furthermore, in the example of the first substrate 20 illustrated in FIG. 4, a conductive pin terminal 25a1 is formed on the conductive plate 20a1, a conductive pin terminal 25a2 is formed on the conductive plate 20a2, and conductive pin terminals 25a3 to 25a6 are formed on the conductive plate 20a3. One end of each of the conductive pin terminals 25a1 to 25a6 is connected to one of the conductive plates 20a1 to 20a3 and the other end of each of the conductive pin terminals 25a1 to 25a6 is connected to the second substrate 30.

Furthermore, in the example of the first substrate 20 illustrated in FIG. 4, a conductive member 25b1 is formed on the conductive plate 20a4 and conductive members 25b2 and 25b3 are formed on the conductive plate 20a3. One end of the conductive member 25b1 is connected to the conductive plate 20a4 and the other end of the conductive member 25b1 is connected to the second substrate 30. One ends of the conductive members 25b2 and 25b3 are connected to the conductive plate 20a3 and the other ends of the conductive members 25b2 and 25b3 are connected to the second substrate 30.

Each of the conductive members 25b1 to 25b3 has, for example, a structure in which a plurality of conductive pins are formed on the upper surface of a block-shaped base portion. One end of a conductive pin is connected to the base portion and the other end of the conductive pin is connected to the second substrate 30. However, the shape of the conductive members 25b1 to 25b3 is not limited to above shape.

With the semiconductor device 10, a three-dimensional wiring structure is formed over the semiconductor chips 21a1 to 21a8 and 21b1 to 21b8 by electrically connecting the first substrate 20 and the second substrate 30 via the post electrodes, the conductive pin terminals, and the conductive members as described above. By adopting the above structure, the second substrate 30 is supported with a predetermined space over the first substrate 20, and the semiconductor chips 21a1 to 21a8 of the upper arm portion A and the semiconductor chips 21b1 to 21b8 of the lower arm portion B are electrically connected to one another through a conductive layer formed on the second substrate 30.

As illustrated in FIGS. 2 and 3, the second substrate 30 is disposed over the first substrate 20 opposite the front surface of the first substrate 20. In the example of FIG. 3, the second substrate 30 has a multilayer structure in which a plurality of conductive layers and a plurality of insulating layers are laminated in the order of a conductive layer 30e, an insulating layer 30d, a conductive layer 30c, an insulating layer 30b, and a conductive layer 30a from the bottom. The number of conductive layers is not limited to this example. The conductive layers 30a, 30c, and 30e may be electrically connected to one another by the above post electrodes, the above conductive pin terminals, the above conductive members, vias, or the like. The second substrate 30 may be referred to as a printed circuit board.

FIG. 5 illustrates examples of conductive plates 30a1, 30a2, 30a3, 30a4, 30a5, 30a6, and 30a7 formed in the front surface of the second substrate 30. The conductive plates 30a1 to 30a7 are conductive plates included in the uppermost conductive layer 30a.

The conductive plate 30a1 is electrically connected to the gate electrodes of the semiconductor chips 21a1 to 21a8 of the upper arm portion A. Eight holes (for example, holes 31a and 31b in FIG. 5) into which the post electrodes connected to the gate electrodes are inserted are made in the conductive plate 30a1. Each hole penetrates the second substrate 30. For example, the post electrode 23g1 illustrated in FIG. 2 is inserted into the hole 31a and the conductive plate 30a1 and a gate electrode 21g of the semiconductor chip 21a1 are electrically connected to each other via the post electrode 23g1. Furthermore, the post electrode 23g2 illustrated in FIG. 2 is inserted into the hole 31b and the conductive plate 30a1 and the gate electrode of the semiconductor chip 21a2 are electrically connected to each other via the post electrode 23g2.

In addition, the conductive plate 30a1 has an exposed portion 32 exposed to the outside of the semiconductor device 10 through an opening 11a (described later) formed in the upper surface of a case 11. A terminal described later is connected to the exposed portion 32. This terminal is used as a control terminal (also referred to as a gate terminal). Furthermore, in order to equalize gate wiring lengths from the gate electrodes of the semiconductor chips 21a1 to 21a8 to the terminals connected to the exposed portion 32, a plurality of slits 33a, 33b, 33c, and 33d are formed in the conductive plate 30a1.

The conductive plate 30a2 is electrically connected to the source electrodes of the semiconductor chips 21a1 to 21a8 of the upper arm portion A. In the conductive plate 30a2, a region (for example, regions 35a and 35b in FIG. 5) having a plurality of holes into which a plurality of post electrodes connected to each source electrode are inserted is formed for each of the semiconductor chips 21a1 to 21a8. Each hole penetrates the second substrate 30.

For example, the post electrodes 23s1 illustrated in FIG. 2 are inserted into the plurality of holes included in the region 35a and the conductive plate 30a2 and the main electrode 21s (source electrode) of the semiconductor chip 21a1 are electrically connected to each other via the post electrodes 23s1. Furthermore, the post electrodes 23s2 illustrated in FIG. 2 are inserted into the plurality of holes included in the region 35a and the conductive plate 30a2 and the source electrode of the semiconductor chip 21a2 are electrically connected to each other via the post electrodes 23s2.

In addition, the conductive plate 30a2 has an exposed portion 36 exposed to the outside of the semiconductor device 10 through an opening 11b (described later) formed in the upper surface of the case 11. A terminal described later is connected to the exposed portion 36. This terminal is used as an auxiliary source terminal. The conductive plate 30a2 electrically connected to the source electrodes of the semiconductor chips 21a1 to 21a8 is used for sharing the auxiliary source terminal for the semiconductor chips 21a1 to 21a8. By doing so, oscillation is suppressed.

The conductive plate 30a3 is electrically connected to the gate electrodes of the semiconductor chips 21b1 to 21b8 of the lower arm portion B and the conductive plate 30a4 is electrically connected to the source electrodes of the semiconductor chips 21b1 to 21b8 of the lower arm portion B. The conductive plate 30a3 has the same structure as the conductive plate 30a1 described above has, and the conductive plate 30a4 has the same structure as the conductive plate 30a2 described above has.

The conductive plate 30a5 is connected to the conductive member 25b2 formed on the first substrate 20, the conductive plate 30a6 is connected to the conductive member 25b3 formed on the first substrate 20, and the conductive plate 30a7 is connected to the conductive member 25b1 formed on the first substrate 20.

Furthermore, holes 37a, 37b, 37c, 37d, 37e, and 37f which the above conductive pin terminals 25a1 to 25a6 penetrate are made in the second substrate 30. The conductive pin terminals 25a1 to 25a6 are electrically connected to one of the conductive layers 30c and 30e included in the second substrate 30.

An insulating resin may be used as an insulating material for the insulating layers 30b and 30d of the second substrate 30 and an insulating material between conductive plates of the conductive layers 30a, 30c, and 30e of the second substrate 30. For example, phenolic resin, epoxy resin, polyimide resin, or glass epoxy resin may be used as the insulating resin. Furthermore, the conductive plates included in the conductive layers 30a, 30c, and 30e of the second substrate 30 are made of metal having good electrical conductivity.

Such metal is, for example, copper, aluminum, or an alloy containing at least one of them. Plating treatment may be performed on the surfaces of the conductive plates to improve corrosion resistance. In this case, a plating material used is, for example, aluminum, nickel, titanium, chromium, molybdenum, tantalum, niobium, tungsten, vanadium, bismuth, zirconium, hafnium, gold, silver, platinum, palladium, or an alloy containing at least one of them.

If the thickness of the second substrate 30 is 1 to 5 mm, then the thickness (thickness d in FIG. 3) of conductive plates 30a1 to 30a7 of the uppermost conductive layer 30a is preferably 50 to 2000 μm in consideration of the fact that terminals are laser-welded to the conductive plates 30a1 to 30a4. If the thickness of the conductive plates 30a1 to 30a7 is less than 50 μm, then a laser beam passes through the conductive plates 30a1 to 30a4, the insulating layer 30b is damaged, and a dielectric breakdown occurs. The conductive plates 30a1 to 30a7 are formed so as to have an appropriate thickness in the range of 50 to 2000 μm according to conditions of laser welding. The thicknesses of conductive plates of the conductive layers 30c and 30e other than the uppermost layer may be the same as or less than that of the conductive plates 30a1 to 30a7 of the conductive layer 30a.

Although not illustrated, a plurality of holes into which position fixing pins are fitted may be made in the first substrate 20 and the second substrate 30 at the same positions in plan view in order to fix the positional relationship between the first substrate 20 and the second substrate 30 on the X-Y plane.

The case 11 of the semiconductor device 10 according to the first embodiment will now be described.

The case 11 incorporates the semiconductor chips 21a1 to 21a8 and 21b1 to 21b8, the first substrate 20, and the second substrate 30. In addition, as illustrated in FIGS. 1 and 3, the case 11 has on the openings 11a, 11b, 11d, and 11c which expose at least a part of the conductive plates 30a1 to 30a4, respectively, of the second substrate 30 of FIG. 5 to the outside. For example, as described above, the exposed portion 32 of FIG. 5 of the conductive plate 30a1 is exposed from the opening 11a and the exposed portion 36 of FIG. 5 of the conductive plate 30a2 is exposed from the opening 11b.

As illustrated in FIG. 1, the openings 11a to 11d are arranged at positions corresponding to half the length of the rectangular case 11 in the short-side direction (X direction) and are arranged in the long-side direction (Y direction) of the case 11.

As described above, by forming the openings 11a to 11d in the upper surface of the case 11 and exposing at least a part of the conductive plates 30a1 to 30a4, respectively, on the front surface of the second substrate 30 to the outside, terminals are connected to the exposed portions later. If the size (opening area) of the openings 11a to 11d is determined in accordance with the area of portions at which the terminals to be used are connected to the conductive plates 30a1 to 30a4, it is possible to ensure sufficiently wide exposed portions so as to ensure the positional accuracy of the terminals.

In the example of FIG. 1, the conductive plates 30a1 and 30a2 having different potentials are exposed to the outside from the different openings 11a and 11b, respectively. The potential of the conductive plate 30a1 is a gate potential and the potential of the conductive plate 30a2 is a source potential. Furthermore, the conductive plates 30a3 and 30a4 having different potentials are exposed to the outside from the different openings 11c and 11d, respectively. The potential of the conductive plate 30a3 is the gate potential and the potential of the conductive plate 30a4 is a source potential.

As described above, the conductive plates on the front surface of the second substrate 30 include first conductive plates (conductive plates 30a1 and 30a3 in the example of FIG. 1) and second conductive plates (conductive plates 30a2 and 30a4 in the example of FIG. 1) having different potentials. Furthermore, at least a part of the first conductive plates and at least a part of the second conductive plates are exposed to the outside from different openings. Accordingly, terminals having different potentials are fixed later to the exposed portions of the first conductive plates and the second conductive plates.

As illustrated in FIGS. 1 and 3, each of the openings 11a to 11d has a tapered shape in which opening area decreases from the upper surface to the lower surface of the case 11. Such a shape facilitates laser welding of the terminals to the conductive plates 30a1 to 30a4.

In FIG. 1, the openings 11a to 11d have a square shape in plan view. However, the shape of the openings 11a to 11d is not limited thereto. For example, the openings 11a to 11d may have a circular shape in plan view.

For example, an insulating resin such as a thermosetting resin may be used as the sealing resin for manufacturing the case 11. For example, the thermosetting resin is epoxy resin, phenolic resin, maleimide resin, or polyester resin. Epoxy resin is preferable. In addition, an underfill material may be used as the sealing resin. The underfill material contains, for example, an epoxy-based resin as a main component, has a curing temperature of about 180° C., and contains a filler material made of an inorganic material. For example, an inorganic material, such as boron nitride, aluminum nitride, or silicon nitride, having high thermal conductivity may be used as the filler material.

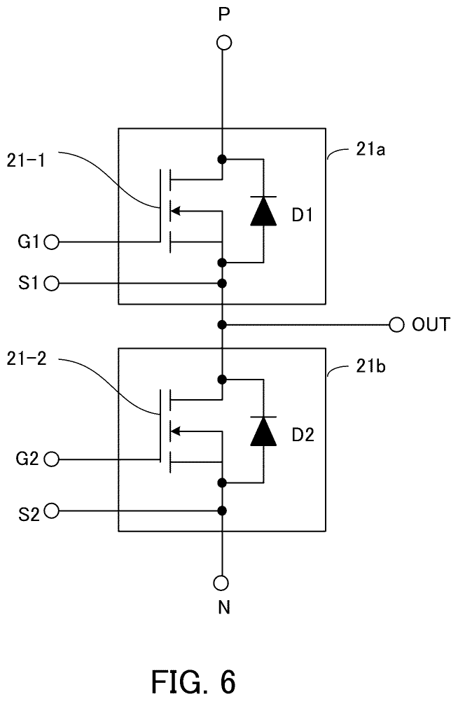

FIG. 6 illustrates an example of the circuit structure of the semiconductor device. In FIG. 6, the semiconductor chips 21a1 to 21a8 of the upper arm portion A are indicated in block by a semiconductor chip 21a and the semiconductor chips 21b1 to 21b8 of the lower arm portion B are indicated in block by a semiconductor chip 21b. The switching element of the semiconductor chip 21a includes a MOSFET 21-1 and a parasitic diode D1 of the MOSFET 21-1. The switching element of the semiconductor chip 21b includes a MOSFET 21-2 and a parasitic diode D2 of the MOSFET 21-2.

A drain electrode of the MOSFET 21-1 is connected to the P terminal and a cathode of the parasitic diode D1. A gate electrode of the MOSFET 21-1 is connected to a gate terminal G1. A source electrode of the MOSFET 21-1 is connected to an anode of the parasitic diode D1, an auxiliary source terminal S1, an output terminal OUT, the drain electrode of the MOSFET 21-1, and a cathode of the parasitic diode D2. A gate electrode of the MOSFET 21-2 is connected to a gate terminal G2. A source electrode of the MOSFET 21-2 is connected to an anode of the parasitic diode D2, an auxiliary source terminal S2, and the N terminal.

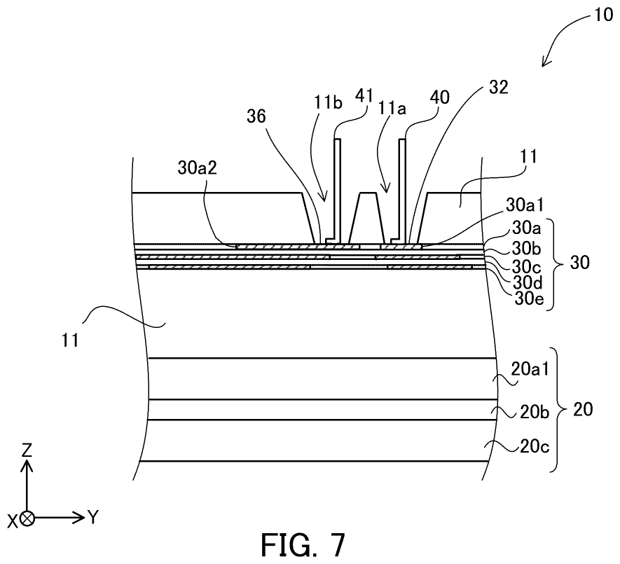

FIG. 7 is a sectional view illustrative of an example of terminal connection. As illustrated in FIG. 7, a terminal 40 (corresponding to the gate terminal G1 in FIG. 6) is connected to the exposed portion (exposed portion 32) of the conductive plate 30a1. A terminal 41 (corresponding to the auxiliary source terminal S1 in FIG. 6) is connected to the exposed portion (exposed portion 36) of the conductive plate 30a2.

The conductive plates 30a1 and 30a2 are preferably connected to the terminals 40 and 41, respectively, by laser welding. If the connection is performed by solder bonding, then heating is needed. If the connection is performed by ultrasonic bonding, then the semiconductor chips may be damaged. Furthermore, laser welding is performed relatively easily.

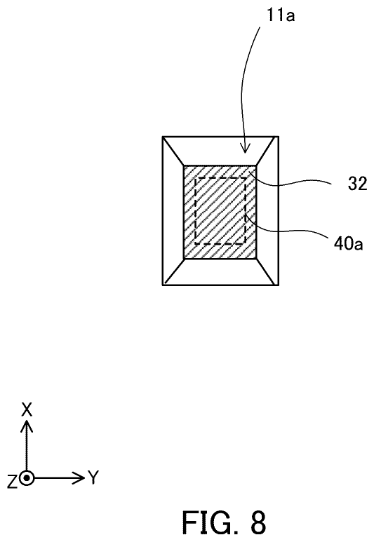

FIG. 8 illustrates the relationship between the area of an exposed portion of a conductive plate and the area of a connection portion of a terminal. As illustrated in FIG. 8, the area of the portion (exposed portion 32) of the conductive plate 30a1 exposed from the opening 11a is larger than the area of a connection portion (connection portion 40a) of the terminal 40 connected to the conductive plate 30a1. This leaves a margin for the positional accuracy of the terminal 40. In addition, laser welding is facilitated. Although not illustrated, the same applies to the relationships between the area of the exposed portions of the other conductive plates 30a2 to 30a4 and the area of connection portions of the terminals connected to the exposed portions.

Incidentally, there is a semiconductor device in which an insulated circuit board on which a semiconductor chip is mounted and a printed circuit board arranged over the insulated circuit board are electrically connected to each other in a state in which the printed circuit board is set in a frame in which control terminals such as press-fit pins are integrally molded, and in which the insulated circuit board and the printed circuit board are sealed with a sealing resin. With this semiconductor device, the semiconductor device is heated in a subsequent burn-in test or other test steps and the positional accuracy of the control terminals and the like may become unstable. In this case, for example, the control terminals of the semiconductor device are not properly connected to a device on the user side because of a positional deviation. As a result, it is difficult to manage the positional accuracy of the control terminals, for example, repeated corrections of a metal mold of the frame are needed.

In contrast, with the semiconductor device 10 according to the present embodiment, terminals are not formed in advance in the case 11. With the semiconductor device 10, at least a part of each of the conductive plates 30a1 to 30a4 on the front surface of the second substrate 30 is exposed to the outside from the openings 11a to 11d, respectively, of the case 11 and terminals are connectable to the exposed portions later. This facilitates management of the positional accuracy of the terminals. That is to say, strict requirements for positional accuracy of the terminals are greatly relaxed.

In addition, the semiconductor chips 21a1 to 21a8 and 21b1 to 21b8 are electrically connected to the second substrate 30 right thereover and the gate terminals are arranged in the exposed portions of the conductive plates 30a1 and 30a3 approximately right over the semiconductor chips 21a1 to 21a8 and 21b1 to 21b8, respectively. As a result, gate wiring length is short compared with a case where control terminals (gate terminals) are formed in the frame. Therefore, gate inductance is reduced, and malfunction of the switching operation of the semiconductor chips 21a1 to 21a8 and 21b1 to 21b8 caused by noise or the like is prevented.

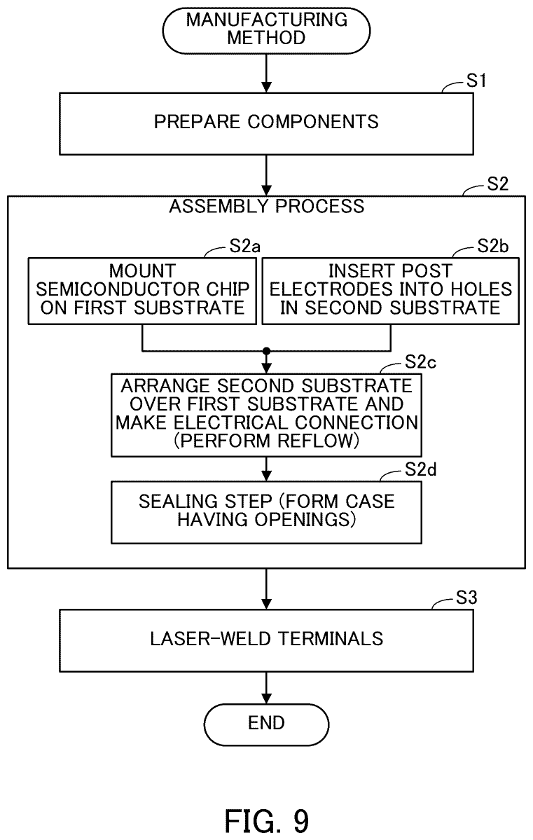

FIG. 9 illustrates an example of a method for manufacturing the semiconductor device according to the first embodiment.

[Step S1] A preparation process for preparing components of the semiconductor device 10 is performed. The components prepared in this process include, for example, the first substrate 20, the second substrate 30, the semiconductor chips 21a1 to 21a8 and 21b1 to 21b8, and the external terminals 12a to 12d. Furthermore, the components include post electrodes (for example, the post electrodes 23g1, 23g2, 23s1, and 23s2 in FIG. 2), the conductive pin terminals 25a1 to 25a6, the conductive members 25b1 to 25b3, and the like. In the preparation process, a component (a cooler or the like) applicable to the semiconductor device 10 may be prepared even if the component is not listed here. Furthermore, a manufacturing apparatus used for manufacturing the semiconductor device 10 may be prepared. The manufacturing apparatus is, for example, an application apparatus for applying solder, a molding apparatus, or a laser welding apparatus.

[Step S2] An assembly process for assembling the semiconductor device 10 is performed. The assembly process includes, for example, the following steps S2a to S2d.

[Step S2a] The semiconductor chips 21a1 to 21a8 and 21b1 to 21b8 are mounted on the first substrate 20. The semiconductor chips 21a1 to 21a8 and 21b1 to 21b8 are arranged on bonding materials (for example, the bonding materials 22a1 and 22a2 illustrated in FIG. 2) formed on the conductive plates 20a1 to 20a3 on the front surface of the first substrate 20. Furthermore, the conductive pin terminals 25a1 to 25a6 and the conductive members 25b1 to 25b3 are also arranged on bonding materials formed on the conductive plates 20a1 to 20a3. In addition, the external terminals 12a to 12d are arranged on bonding materials formed on the conductive plates 20a1 to 20a4.

The conductive pin terminals 25a1 to 25a6 may be arranged in a later step. In this case, bonding materials are formed at portions to which the conductive pin terminals 25a1 to 25a6 are connected.

[Step S2b] Post electrodes (for example, the post electrodes 23g1, 23g2, 23s1, and 23s2 in FIG. 2) are inserted into a plurality of holes (for example, the holes 31a and 31b or the plurality of holes in the regions 35a and 35b in FIG. 5) in the second substrate 30.

If the conductive pin terminals 25a1 to 25a6 are not arranged in step S2a, then the conductive pin terminals 25a1 to 25a6 are inserted into the holes 37a to 37f, respectively, of the second substrate 30 in step S2b.

Step S2b may be performed before or after step S2a. Alternatively, step S2b may be performed in parallel with step S2a.

[Step S2c] The second substrate 30 is arranged over the first substrate 20. The second substrate 30 having the conductive plates 30a1 to 30a7 on the front surface is arranged with the back surface facing the front surface of the first substrate 20. At this time, one ends of the post electrodes inserted into the holes of the second substrate 30 are arranged so as to be in contact with bonding materials (for example, the bonding materials 22b1 and 22b2 in FIG. 2) formed on the gate electrodes and the source electrodes on the upper surfaces of the semiconductor chips 21a1 to 21a8 and 21b1 to 21b8. Furthermore, the conductive members 25b1 to 25b3 formed on the first substrate 20 are connected to the second substrate 30. If the conductive pin terminals 25a1 to 25a6 are formed on the first substrate 20, then the conductive pin terminals 25a1 to 25a6 are connected to the second substrate 30.

In step S2c, reflow is performed in a state in which the first substrate 20 and the second substrate 30 are arranged in the above way. As a result, the semiconductor chips 21a1 to 21a8 and 21b1 to 21b8 are electrically connected to the conductive plates 30a1 to 30a7 and the like.

[Step S2d] A sealing step is performed. In the sealing step, for example, the case 11 having the openings 11a to 11d illustrated in FIG. 1 on the upper surface and incorporating the semiconductor chips 21a1 to 21a8 and 21b1 to 21b8, the first substrate 20, and the second substrate 30 is formed.

In this step, the first substrate 20 to which the second substrate 30 is attached is set in a cavity of a metal mold of a predetermined molding apparatus. The metal mold has a shape capable of forming the openings 11a to 11d having the shapes illustrated in FIGS. 1 and 3. In the molding apparatus, a molten sealing raw material in a pod is pressurized by a plunger, is fed from the pod to a runner, and is injected into the cavity. After that, the sealing raw material is cured. As a result, the case 11 which seals the semiconductor chips 21a1 to 21a8 and 21b1 to 21b8, the first substrate 20, and the second substrate 30 and which has the openings 11a to 11d that expose at least a part of the conductive plates 30a1 to 30a4, respectively, to the outside is formed.

In the assembling process, a cooler may be bonded to the lower surface of the semiconductor device 10 with a bonding material therebetween.

[Step S3] After that, the terminals (gate terminals or the auxiliary source terminals) are laser-welded to the conductive plates 30a1 to 30a4 exposed from the openings 11a to 11d, respectively (see FIG. 7). The laser welding may be performed by a user of the semiconductor device 10.

The semiconductor device 10 according to the first embodiment is manufactured by the above manufacturing method.

With the above semiconductor device 10, terminals having different potentials are fixed later to exposed portions of both of first conductive plates (conductive plates 30a1 and 30a3 in the example of FIG. 1) and second conductive plates (conductive plates 30a2 and 30a4 in the example of FIG. 1). However, the present disclosure is not limited to this case. If terminals having one potential (for example, auxiliary source terminals) are not used, then there is no need to form openings which expose at least a part of the second conductive plates.

### Second Embodiment

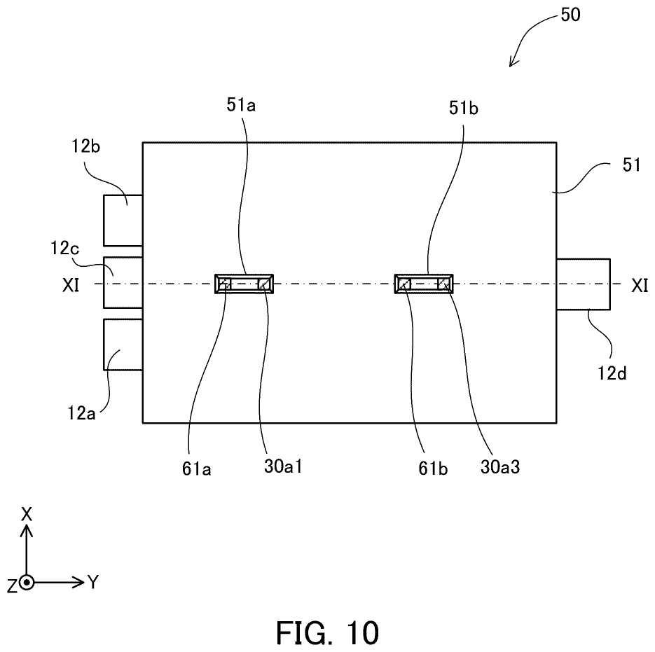

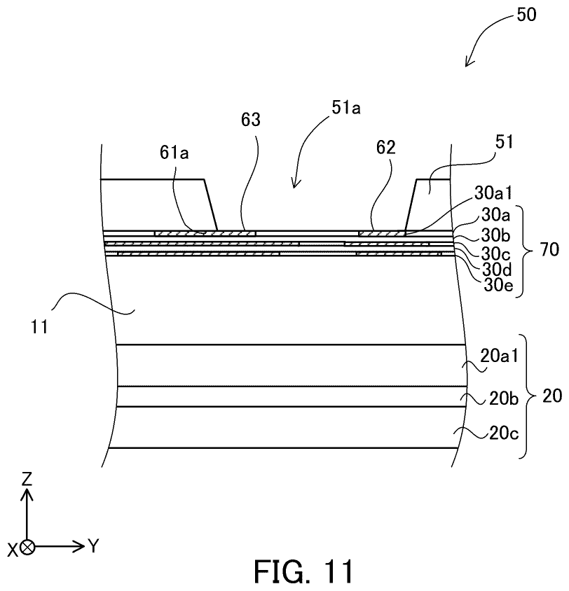

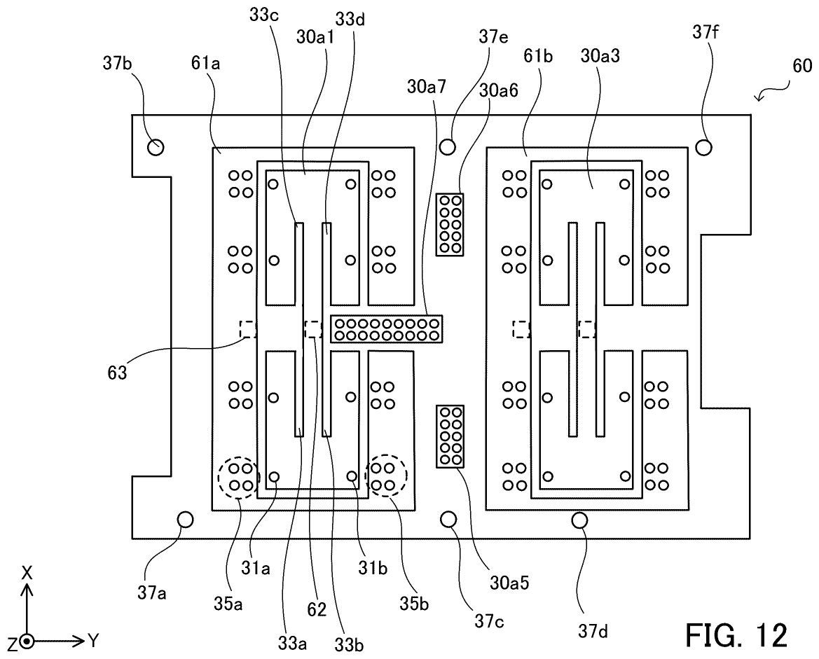

FIG. 10 is a top view of an example of a semiconductor device according to a second embodiment. FIG. 11 is a sectional view illustrative of a part of a section taken along the line XI-XI in FIG. 10. FIG. 12 is a top view of an example of a second substrate in the semiconductor device according to the second embodiment. In FIGS. 10 to 12, components which are the same as those illustrated in FIGS. 1, 3, and 5 are marked with the same numerals.

With a semiconductor device 50 according to the second embodiment, a case 51 and a second substrate 60 are different from the case 11 and the second substrate 30, respectively, of the semiconductor device 10 according to the first embodiment.

Conductive plates on the front surface of the second substrate 60 include first conductive plates (conductive plates 30a1 and 30a3 in the example of FIG. 12) and second conductive plates (conductive plates 61a and 61b in the example of FIG. 12) having different potentials. Furthermore, as illustrated in FIG. 10, at least a part of the first conductive plates and at least a part of the second conductive plates are exposed to the outside from common openings 51a and 51b of the case 51.

In the example of FIG. 10, parts of the conductive plates 30a1 and 61a are exposed from the opening 51a and parts of the conductive plates 30a3 and 61b are exposed from the opening 51b. FIG. 12 illustrates an exposed portion 62 of the conductive plate 30a1 and an exposed portion 63 of the conductive plate 61a. If the conductive plates 30a1 and 61a having different potentials are exposed from the common opening 51a, then it is desirable to ensure creepage distance between the conductive plates 30a1 and 61a at the time of laser-welding terminals from the viewpoint of preventing a short circuit. Therefore, the distance (distance in the Y direction) between the exposed portions 62 and 63 is longer than the distance between the exposed portions 32 and 36 of the second substrate 30 illustrated in FIG. 5.

With the semiconductor device 50 according to the second embodiment, the same effects that are obtained by the semiconductor device 10 according to the first embodiment are obtained. In addition, by exposing at least a part of the first conductive plates and at least a part of the second conductive plates to the outside from the common opening, the number of openings is reduced compared with a case where first conductive plates and second conductive plates are exposed from different openings.

The semiconductor device 50 is manufactured by the same method that is illustrated in FIG. 9.

In one aspect, it is easy to manage the positional accuracy of terminals.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip having a plurality of main electrodes and a gate electrode;
a first substrate on which the semiconductor chip is mounted;
a second substrate located above the first substrate, the second substrate having a conductive plate on a front surface thereof, the conductive plate being electrically connected to the semiconductor chip; and
a case having an opening in an upper surface thereof, at least a part of the conductive plate being exposed through the opening, the case incorporating the semiconductor chip, the first substrate, and the second substrate.

2. The semiconductor device according to claim 1, further comprising a terminal connected to the conductive plate exposed from the opening.

3. The semiconductor device according to claim 2, wherein
the terminal has a connection portion, at which the terminal is connected to the conductive plate, and
the part of the conductive plate exposed from the opening has an area that is larger than an area of the connection portion.

4. The semiconductor device according to claim 1, wherein:
the second substrate is a printed circuit board having a plurality of insulating layers and a plurality of conductive layers laminated therein; and
the conductive plate is included in an uppermost one of the plurality of conductive layers.

5. The semiconductor device according to claim 1, wherein the conductive plate has a thickness of 50 μm or more and 2000 μm or less.

6. The semiconductor device according to claim 1, wherein the opening has a tapered shape to become gradually smaller from the upper surface to a lower surface of the case.

7. The semiconductor device according to claim 1, wherein:
the conductive plate includes a first conductive plate and a second conductive plate having different potentials,
the opening includes one or a plurality of openings, and
at least a part of the first conductive plate and at least a part of the second conductive plate are exposed from a same one of the one or the plurality of openings, or different ones of the plurality of openings.

8. The semiconductor device according to claim 7, wherein:
the first conductive plate is electrically connected to the gate electrode; and
the second conductive plate is electrically connected to one of the plurality of main electrodes.

9. A method of manufacturing a semiconductor device, comprising:
providing a first substrate;
mounting a semiconductor chip having a plurality of main electrodes and a gate electrode on the first substrate;
arranging a second substrate having a conductive plate on a front surface thereof over the first substrate, and electrically connecting the semiconductor chip and the conductive plate; and
forming a case having an opening on an upper surface thereof, to expose at least a part of the conductive plate from the opening, the case incorporating the semiconductor chip, the first substrate, and the second substrate.

10. The method according to claim 9, further comprising laser-welding a terminal to the conductive plate exposed from the opening.
